(19) United States
(12) Patent Application Publication
(10) Pub. No.: US 2026/0136876 A1
(43) Pub. Date: May 14, 2026

(54) APPARATUS, SYSTEMS, AND ASSOCIATED METHODS FOR MONITORING PROCESS DRIFT IN A SEMICONDUCTOR PROCESSING SYSTEM

(71) Applicant: ASM IP Holding B.V., Almere (NL)

(72) Inventor: Salam Harb, Scottsdale, AZ (US)

(21) Appl. No.: 18/947,941

(22) Filed: Nov. 14, 2024

(51) Int. Cl. H01L 21/67; G01B 7/14; G01B 11/14; H01L 21/66

(52) U.S. Cl. CPC H10P 72/0604; G01B 7/14; G01B 11/14; H10P 74/238

(57) ABSTRACT

Load lock assemblies, semiconductor processing systems including such load lock assemblies, and associated methods for monitoring process drift within a process module of a semiconductor processing system are disclosed. The load lock assemblies disclosed include an indexer mechanism and position sensor in communication with a controller in a feedback loop configuration to enable the generation of a control parameter based on the weight or the weight change of a substrate within the load lock assembly. The control parameter is used to signal when a process drift is detected to enable corrective measures to be performed.

### CROSS-REFERENCE TO RELATED APPLICATION(S)

This Application claims the benefit of U.S. Provisional Application filed on, the entire contents of which are incorporated herein by reference.

### FIELD

The present disclosure generally relates to the field of semiconductor processing systems and processing methods, and to the field of device and integrated circuit manufacture. More particular, the present disclosure relates to apparatus, systems, and methods for monitoring process drift in a semiconductor processing system.

### BACKGROUND

Semiconductor devices and integrated circuits are typically fabricated on a substrate of semiconductor material, often referred to as a substrate, wafer, and/or workpiece. Processing methods commonly used in the fabrication of semiconductor devices and integrated circuits include, but are not limited to, vapor deposition processes (e.g., atomic layer deposition, chemical vapor deposition, etc.) and etching processes (e.g., chemical vapor etching, atomic layer etching, plasma based etching etc.). These processes generally involve forming or removing a layer of material on/from an exposed surface of the substrate. The parameters governing such processes are commonly tightly controlled to ensure that each substrate subjected to a particular process has substantially the same amount of material added or removed, with any deviation from the expected process being commonly referred to as “process drift”.

In some semiconductor manufacturing processes, unprocessed substrates are transported from cassettes into a load lock arrangement. Substrates are then transported from the load lock arrangement to a process module for processing. Once a process is complete in one process module, the substrate can be transferred to a different process module to continue processing the substrate. During the transfer of substrate between different process modules the substrate can pass through the load lock arrangement multiple times. Once processing of the substrate is complete the substrate is typically moved back to load lock arrangement for cooling, post-processing and transport (e.g., out of the semiconductor processing system). Such load lock arrangements can incorporate apparatus and systems to allow for improved utilization of the semiconductor processing system. For example, cooling and heating of a substrate within a load lock arrangement can be employed to reduce the process time within the individual process modules. However, there remains a need for improved load lock arrangements, such as load lock arrangements that incorporate additional functionality to enable the monitoring of process drift during the processing of multiple substrates. Accordingly, improved load lock arrangements, semiconductor processing system including such improved load lock arrangements, and associated methods for monitoring process drift within such improved load lock arrangements are desirable.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to apparatus, systems, and associated methods for monitoring process drift in a semiconductor processing system and particularly in a load lock arrangement. As set forth in more detail below, the apparatus of the present disclosure include load lock arrangements configured and arranged to monitor parameter(s) proportional to the weight of a substrate within the load lock arrangement by employing at least an indexer mechanism, sensor(s), and a controller in a feedback loop configuration. Such an arrangement is able to generate a control parameter proportional to the weight or a change in the weight of substrate having undergone a particular process in a process module and subsequently compare the control parameter against a predetermined expected value, or range of acceptable values.

In accordance with examples of the disclosure, an apparatus for monitoring process drift within a semiconductor processing system is provided. An example apparatus includes, a load lock arrangement including a load lock body and an indexer mechanism connected to the load lock body, the indexer mechanism including a drive mechanism and a means for supporting a substrate. In such examples the apparatus also includes, a position sensor configured and arranged to measure a deflection distance of the indexer mechanism from a known neutral position upon seating a substrate on the indexer mechanism and subsequently the position sensor generates a feedback signal based on the deflection distance. In such examples the apparatus also includes a controller configured and arranged to receive the feedback signal and subsequently the controller calculates and provides a delta drive current (ΔI) to the drive mechanism to reposition the indexer mechanism back to the known neutral position, where the delta drive current (ΔI) is proportional to the weight of the substrate when the acceleration of the drive mechanism is zero and a vacuum load is constant, such that the controller is enabled to generate a control parameter proportional to either the weight of the substrate or a change in the weight of the substrate. In such examples, the apparatus also includes an alert system in communication with the controller wherein the alert system is activated if the controller determines that the control parameter is outside a predetermined acceptable range of values.

In accordance with additional examples of the disclosure, a semiconductor processing system is provided. In such examples, the semiconductor processing system includes a load lock arrangement including a load lock body, an equipment front-end module (EFEM) connected to a front face of the load lock body, the equipment front-end module housing a front-end substrate transfer robot, and a back-end transfer module (BETM) connected to a rear face of the load lock body, the back-end transfer module coupling a process module to the load lock body. In such examples the semiconductor processing system also includes an indexer mechanism connected to the load lock body, the indexer mechanism including a drive mechanism and a means for supporting a substrate. In such examples the semiconductor processing system also includes a position sensor configured and arranged to measure a deflection distance of the indexer mechanism from a known neutral position upon seating a substrate on the indexer mechanism and subsequently the position sensor generates a feedback signal based on the deflection distance. In such examples the semiconductor processing system also includes a controller configured and arranged to receive the feedback signal and subsequently the controller calculates and provides a delta drive current (ΔI) to the drive mechanism to reposition the indexer mechanism to the known neutral position, where the delta drive current (ΔI) is proportional to the weight of the substrate when the acceleration of the drive mechanism is zero and a vacuum load is constant, such that the controller is enabled to generate a control parameter proportional to a change in the weight of the substrate by determining the difference between a first delta drive current (ΔI₁) for a substrate transferred and seated on the indexer mechanism from the EFEM and a second delta drive current (ΔI₂) for a substrate transferred and reseated on the indexer mechanism from the BETM after the substrate has been subjected to one or more process within the process module. In such examples the semiconductor processing system also includes, an alert system in communication with the controller wherein the alert system is activated if the controller determines that the control parameter is outside a predetermined acceptable range of values.

In accordance with additional examples of the disclosure, a method of monitoring process drift in a semiconductor processing system is provided. In such examples the method includes, at an indexer mechanism connected to a load lock body, the indexer mechanism including a drive mechanism and a means for supporting a substrate. In such examples the method also includes transferring a substrate into the load lock body and seating the substrate on the indexer mechanism. In such examples the method also includes generating a first feedback signal from a position sensor configured and arranged to measure a first deflection distance of the indexer mechanism from a known neutral position upon seating the substrate on the indexer mechanism, and calculating a first delta drive current (ΔI₁) from the first feedback signal and providing the first delta drive current (ΔI₁) to the drive mechanism to reposition the indexer mechanism back to the known neutral position, where the first delta drive current (ΔI) is proportional to the first weight of the substrate when the acceleration of the drive mechanism is zero and a vacuum load is constant. In such examples the method also includes transferring the substrate from the load lock body into a process module and performing one or more processes on the substrate and subsequently transferring the substrate from the process module back into the load lock body and reseating the substrate on the indexer mechanism. In such examples the method also includes generating a second feedback signal from the position sensor configured and arranged to measure a second deflection distance of the indexer mechanism from the known neutral position upon reseating the substrate on the indexer mechanism. In such examples the method also includes calculating a second delta drive current (ΔI₂) from the second feedback signal and providing the second delta drive current (ΔI₂) to the drive mechanism to reposition the indexer mechanism back to the known neutral position, where the second delta drive current (ΔI) is proportional to the second weight of the substrate when the acceleration of the drive mechanism is zero and the vacuum load is constant. In such examples the method also includes calculating a control parameter proportional to a change in the weight of the substrate by determining the difference between the first delta drive current (ΔI) and the second delta drive current (ΔI), and activating an alert system if the control parameter is outside a predetermined acceptable range of values.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of exemplary embodiments of the present disclosure can be derived by referring to the detailed description and claims when considered in connection with the following illustrative figures.

FIG. 1 illustrates a semiconductor processing system according to at least one of the embodiments of the present disclosure.

FIG. 2 illustrates a load lock arrangement according to at least one of the embodiments of the present disclosure.

FIG. 3 illustrates a dual chamber load lock arrangement according to at least one of the embodiments of the present disclosure.

FIG. 4 illustrates a method for monitoring process drift in a semiconductor processing system according to at least one of the embodiments of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of apparatus, systems, and methods provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “load lock arrangement” can refer to any chamber arrangement which is configured for the handling, transferring, and/or storage of substrates prior to and/or post processing in a process module (or reactor, reaction chamber, and the like).

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

Various embodiments of the present disclosure relate to apparatus, systems, and methods for monitoring process drift in a semiconductor processing system and particularly in a load lock arrangement. As set forth in more detail below, the apparatus of the present disclosure include load lock arrangements configured and arranged to monitor parameter(s) proportional to the weight of a substrate. Such apparatus therefore enable monitoring of a weight change of a substrate subjected to a deposition and/or etch process, for example. The weight change of a particular substrate, pre and post processing, can be used to determine if process drift has occurred when comparing such weight changes against predetermined expected values, or range of acceptable values.

In accordance with examples of the disclosure, the load lock arrangements of the present disclosure employ an indexer mechanism, incorporating a vertical actuator assembly including a drive mechanism, such as a servo system with a linear drive, and a high precision position sensor to generate a control parameter based on the weight or weight change of a substrate. In various embodiments of the disclosure, the indexer mechanism can be configured to maintain a substrate seated thereon, at a known neutral position (i.e., a baseline vertical position within the load lock arrangement) which is typically the position within the load lock arrangement at which the substrate is either loaded or unloaded.

In accordance with examples of the disclosure, the indexer mechanism is controlled in a feedback loop configuration. In such examples, the position sensor measures a deflection distance of the indexer mechanism from a known neutral position caused by seating a substrate on the indexer mechanism. In such examples, the position sensor generates a feedback signal based on the deflection distance which is sent to a controller in communication with the position sensor and the indexer mechanism. In turn, the controller determines from the feedback signal the change in the drive current (referred to herein as the delta drive current) provided to the drive mechanism to enable repositioning of the substrate back to the known neutral position. When controlling certain variables/parameters within the load lock arrangement and the indexer mechanism, the delta drive current (ΔI) is proportional to the weight of the substrate (to be described in more detail herein) therefore enabling the controller to generate a control parameter proportional to either the weight of a substrate or the change in the weight of a substrate. If it is determined that the control parameter is outside a predetermined acceptable value or range of values, then an alert system, either connected to the controller or integral to the controller can be activated to alert that a process drift has been detected thereby allowing for suitable corrective action(s) to be performed.

Previous apparatus, systems, and methods for determining process drift in semiconductor processing systems commonly utilize ex-situ apparatus and methods. In such previous apparatus and methods, substrates are commonly removed from the semiconductor processing system and evaluated using ex-situ metrology tools to determine if the semiconductor processing system is experiencing process drift. Such ex-situ apparatus and methods disadvantageous result in reduced substrate throughput, the need for costly metrology tools, and exposure of substrates to atmosphere, for example.

The embodiments of the present disclosure advantageously employ in-situ apparatus, systems, and methods for monitoring process drift. For example, substrates are commonly seated and reseated in the load lock arrangement of the present disclosure multiple times as they are transferred back and forth between various process modules. Each seating and reseating of a substrate within the load lock arrangements of the present disclosure allows for a rapid determination of the change in the weight of the substrate immediately after having undergone a process in one of the process modules. The determination of the weight change of the substrates is precise and rapid and therefore does not affect throughput of substrates through the semiconductor processing system. In addition, a process drift within one of the process modules can be rapidly detected resulting in the immediate deployment of corrective action, thus preventing scraped substrates, unwanted expense, and tool down time.

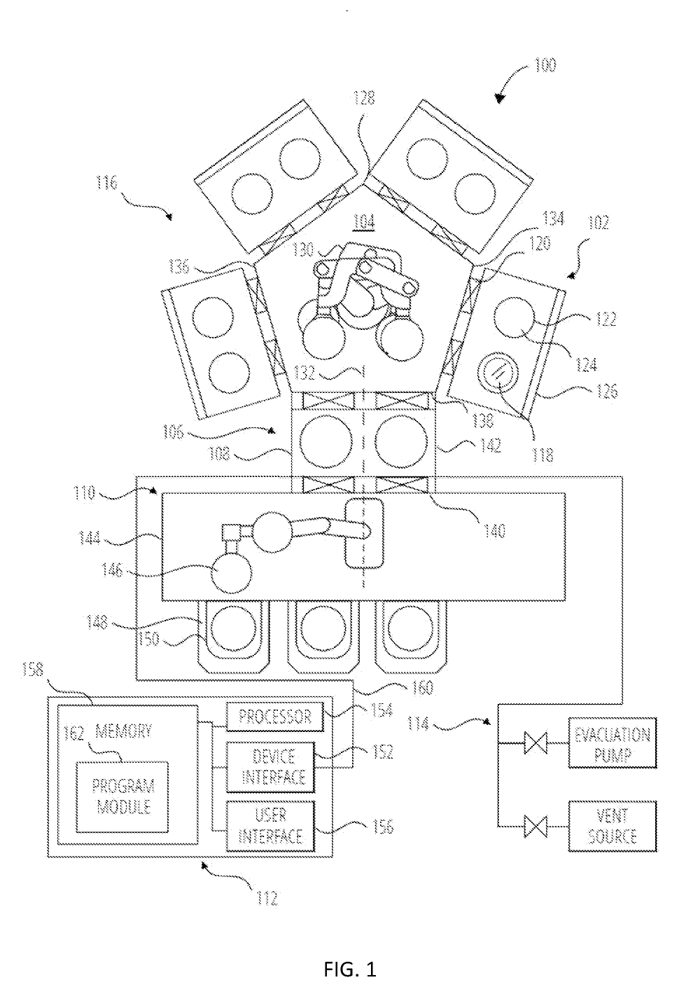

Turning now to the figures, FIG. 1 illustrates a semiconductor processing system 100 of the present disclosure, including a load lock arrangement 106 for enabling monitoring of process drift. The semiconductor processing system 100 includes a process module 102, a back-end transfer module 104, and a load lock arrangement 106 including load lock body 108. The semiconductor processing system 100 also includes an equipment front-end module (EFEM) 110, a controller 112, and an evacuation/venting source 114. In the illustrated example the semiconductor processing system 100 includes a cluster-type platform 116 with four (4) process modules configured to deposit/etch a material layer onto/from a substrate 118 using deposition and/or etch processes, such as, atomic layer deposition (ALD), chemical vapor deposition (CVD), plasma-enhanced chemical vapor deposition (PECVD), plasma-enhanced atomic layer deposition (PEALD), atomic layer etch (ALEt) processes, chemical vapor etch (CVE) processes, and plasma based dry-etch processes, for example. This is for illustration and description purposes only and is non-limiting. As will be appreciated by those of skill in the art in view of the present disclosure, semiconductor processing systems configured for other material layer deposition/etch operations as well as semiconductor processing systems configured for other processing operations can also benefit from the present disclosure.

The process module 102 is coupled to the back-end transfer module 104 by a process module gate valve 120. The process module 102 includes a process chamber 122, a heater 124, and a reactant source 126. The process chamber 122 is arranged within the process module 102, houses the heater 124, and is configured to flow a precursor or reactant across the substrate 118 while seated on the heater 124 during deposition/etch of a material layer onto/from the substrate 118. The precursor/reactant source 126 is fluidly coupled to the process chamber 122 and configured to provide the precursor/reactant to the process chamber 122 for deposition/etch of the one or more material layers onto/from the substrate 118. The process module gate valve 120 couples the process module 102 to the back-end transfer module 104 and is configured to provide selective communication between the process chamber 122 and the back-end transfer module 104. In this respect it is contemplated that the process module gate valve 120 can be configured to permit transfer of the substrate 118 between the back-end transfer module 104 and the process module 102 before and after deposition of material layer(s) onto the substrate 118.

In accordance with examples of the disclosure, the process chamber 122 may be a first process chamber and the process module 102 may include one or more second process chambers. For example, the process module 102 may be a dual chamber module having two (2) process chambers or a quad chamber module having four (4) process chambers. In accordance with certain examples, the process module gate valve 120 may be a first process module gate valve and the process module 102 may include a second process module gate valve also coupling the process module 102 to the back-end transfer module 104. It is contemplated that, in certain examples, the reactant may include a reactant or a precursor suitable for deposition/etch of a material layer. It is also contemplated that, in accordance with certain examples, the process module 102 includes a plasma unit configured to provide the reactant to the substrate 118 as a suitable plasma. In this respect the process module 102 may be configured to deposit/etch a material layer onto/from the substrate 118 using a plasma-enhanced deposition/etch technique by way of example.

The back-end transfer module 104 is coupled to a rear face 138 of the load lock body 108 and includes a back-end chamber body 128 and a back-end substrate transfer robot 130. The back-end chamber body 128 is arranged along a transfer axis 132. It is contemplated that the back-end substrate transfer robot 130 be arranged within an interior of the back-end chamber body 128 and supported within the back-end chamber body 128 for movement relative to the back-end chamber body 128 for transfer of substrates, e.g., the substrate 118, between the load lock arrangement 106 and the process module 102. In certain examples, the back-end chamber body 128 may have a polygonal shape. In this respect the back-end chamber body 128 may have five sides, fewer than five sides (e.g., a rectangular or square shape), or more than five sides (e.g., a hexagonal shape), and may have the shape of a regular polygon or an irregular polygon.

The equipment front-end module (EFEM) 110 is coupled to a front face 140 of the load lock body 108 and includes an enclosure 144, a front-end substrate transfer robot 146, and one or more load port 148. The enclosure 144 houses the front-end substrate transfer robot 146. The front-end substrate transfer robot 146 is housed within the enclosure 144 for movement relative to the enclosure 144 or transfer of substrates, e.g., the substrate 118, between the one or more load ports 148 and the load lock arrangement 106. The one or more load ports 148 are connected to the enclosure 144 and are configured to seat therein a pod 150 housing one or more substrates, prior to and subsequent to deposition/etch of material layers onto/from the substrates. In certain examples, the pod 150 may include a standard mechanical interface pod. In accordance with certain examples, the pod 150 may include a front-opening unified pod. Although shown and described herein as having three (3) load ports it is to be understood and appreciated that equipment front-end module 110 may include fewer or additional load ports and remain within the scope of the present disclosure.

The controller 112 is operably connected to the semiconductor processing system 100 and includes a device interface 152, a processor 154, a user interface 156, and a memory 158. The device interface 152 couples the processor 154 to the semiconductor processing system 100, for example, through (or over) a wired or wireless link 160. The processor 154 is operably connected to the user interface 156 and is disposed in communication with the memory 158. The memory 158 includes a non-transitory machine-readable medium having a plurality of program module 162 recorded thereon containing instructions that, when read by the processor 154, cause the processor 154 to execute certain operations. Among the operations are operations for monitoring process drift in the semiconductor processing system 100, as will be described below.

In some embodiments, the semiconductor processing system 100 can include substrate heating and/or substrate cooling within the load lock arrangement 106, such as for throughput purposes. For example, in some semiconductor processing systems, substrate heating within the load lock arrangement can be implemented to limit processing time within the process module to shortening the time taken to ramp the substrate temperature to a desired material layer deposition temperature. Alternatively, or additionally, substrate cooling within the load lock arrangement 106 may be implemented to limit processing time within the process modules. In accordance with examples of the disclosure, the load lock arrangement 106 further includes an indexer mechanism, which in conjunction with the controller 112 and position sensor(s) can monitor process drift in the process modules 102 of the semiconductor processing system 100.

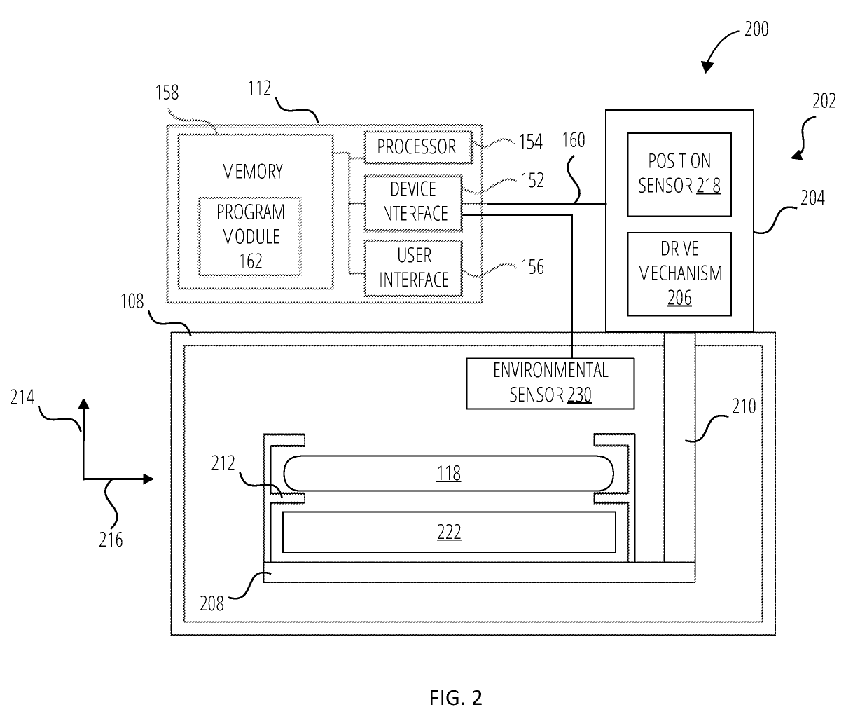

FIG. 2 illustrates an exemplary load lock arrangement 200 in accordance with embodiments of the present disclosure and illustrates a simplified cross-sectional view of an exemplary internal configuration of the load lock elements within the load lock arrangement 200.

In more detail, the load lock arrangement 200 includes a load lock body 108. The load lock body 108 includes a front face configured for coupling with an equipment front-end module and a rear face configured for coupling with a back-end transfer module, as illustrated in FIG. 1.

In accordance with examples of the disclosure, the load lock arrangement 200 (FIG. 2) includes an indexer mechanism 202 connected to the load lock body 108. In some embodiments, the indexer mechanism 202 is partially disposed in the load lock body 108 (as illustrated in FIG. 2) or alternatively fully disposed within the load lock body 108. In accordance with examples of the disclosure, the indexer mechanism 202 comprises a vertical actuator assembly 204 including a drive mechanism 206. In such examples, the drive mechanism 206 is connected to a support arm 208 by way of vertical support member 210. In some embodiments, the support arm 208 includes one or more substrate handling members 212 configured to seat one or more substrate 118 within the load lock body 108. In some embodiments, the support arm 208 includes multiple substrate handling members 212 to enable multiple substrates to be stacked and spaced apart in a vertical stack.

In accordance with examples of the disclosure, the vertical actuator assembly 204 includes a drive mechanism 206 configured to translate the support arm 208 along a vertical axis 214. The support arm 208 may be cantilevered and extend from the vertical support member 210 along a horizontal axis 216. The vertical actuator assembly 204 can include any of a variety of drive mechanisms 206 known to those of skill in the art to effectuate linear motion along the vertical axis 214 including, but not limited to, a voice coil, a servo motor, a linear motor, or other conventional mechanical linear actuation devices. In such examples, the drive mechanism 206 has a positioning accuracy of less than 1 nanometer, or less.

In accordance with examples of the disclosure, the load lock arrangement 200 also includes a position sensor 218. In some embodiments, the position sensor 218 is integral to the indexer mechanism 202, as illustrated in FIG. 2. In alternative embodiments, the position sensor 218 can be a separate unit from the indexer mechanism 202 but linked (e.g., electrical, optically, wireless, etc.) to enable communication between the position sensor 218 and the indexer mechanisms 202. In some embodiments, the vertical actuator assembly 204 can include two or more position sensors. In some embodiments, the position sensor 218 comprises a linear position sensor. In such examples, the linear position sensor can be integrated within the indexer mechanism 202.

In accordance with examples of the disclosure, the position sensor 218 is configured and arranged to measure a deflection distance of the indexer mechanism 202 from a known neutral position upon seating a substrate on the indexer mechanism 202. In more detail, when a substrate 118 is transferred into the load lock body 108 and seated on the indexer mechanism 202, the weight of the substrate 118 causes the indexer mechanism 202 to deviate from a known neutral position and the position sensor 218 measures the amount of deviation from the known neutral position as the deflection distance of the indexer mechanism 202 from the known neutral position. In such examples, the position sensor 218 converts the deflection distance to an electrical signal and from this generates a feedback signal based on the deflection distance (to be described in greater detail below).

In accordance with examples of the disclosure, the position sensor 218 can include any of a variety of position sensors known to those of skill in the art to determine the deflection distance of the indexer mechanism 202 from the known neutral position. In some embodiments, the position sensor 218 comprises one or more of an optical sensor (e.g., laser interferometer/laser triangulation sensor, Michelson interferometer, etc.), a magnetic sensor (e.g., a hall-effect/magnetostrictive sensors), an electrical sensor (e.g., a resistive/capacitive/inductive based sensors), or other known precision position sensors. In some embodiments, the position sensor is a capacitive base sensor, such as a parallel plate capacitor sensor. In some embodiments, the position sensor is an optical sensor, such as a laser triangulation displacement sensor. In some embodiments, the position sensor has a measurement accuracy of less than 1 nanometer, or less.

The load lock arrangement 200 further comprises a controller 112. In some embodiments, the controller is the same as controller 112 as described with reference to FIG. 1 or in alternative embodiments a separate controller may be employed. The controller 112 is operably connected to the load lock arrangement 200 and includes a device interface 152, a processor 154, a user interface 156, and a memory 158. The device interface 152 couples the processor 154 to the load lock arrangement 200, for example, through (or over) a wired or wireless link 160. The processor 154 is operably connected to the user interface 156 and is disposed in communication with the memory 158. The memory 158 includes a non-transitory machine-readable medium having a plurality of program module 162 recorded thereon containing instructions that, when read by the processor 154, cause the processor 154 to execute certain operations. Among the operations are operations for monitoring process drift in the load lock arrangement 200, as will be described below.

In accordance with examples of the disclosure, the controller 112 can be configured in a feedback control loop with the position sensor 218, the indexer mechanism 202, and particularly with the drive mechanism 206. In some embodiments, the controller 112 is configured and arranged to receive the feedback signal (generated by the position sensor 218) and subsequently calculate and provide a delta drive current (ΔI) to the drive mechanism 206 to reposition the indexer mechanism back to the known neutral position. In such examples, the delta drive current (ΔI) is proportional to the weight of the substrate when the acceleration of the drive mechanism is zero and a vacuum load is constant, such that the controller is enabled to generate a control parameter proportional to either the weight of the substrate or a change in the weight of the substrate.

In more detail, the indexer mechanism 202, when under zero substrate load (i.e., when no substrates are seated on substrate handling members 212), is positioned at a known neutral position. This known neutral position is achieved by supplying a drive current (I) to the drive mechanism 206 of the indexer mechanism 202. When a substrate 118 is transferred into the load lock body 108 and seated on the indexer mechanism 202, the weight of the substrate 118 causes the indexer mechanism 202 to deviate from the known neutral position and the position sensor 218 measures the amount of deviation and generates the feedback signal based on this deviation. The feedback signal is communicated to the controller 112 which calculates the change in current needed by the drive mechanism 206 to enable the repositioning of the indexer mechanisms 202 back to the known neutral position. This change in drive current to the drive mechanism 206, i.e., the delta drive current (ΔI), is directly proportional to the weight of the substrate seated on the indexer mechanism 202 when the acceleration of the drive mechanism 206 is zero, and the vacuum load on the indexer mechanism 202 is constant. In such examples, the delta drive current (ΔI) ∝ weight of the substrate (Wₛ) (i.e., ΔI ∝ Wₛ) and knowing this relationship the delta drive current (ΔI) can be utilized as a control parameter for monitoring and alerting a user/controller to the process drift. In exemplary embodiments, the acceleration of the drive mechanism is defined herein as the inertia force exerting at the drive mechanism.

As a non-limiting example, the controller 112 can generate a control parameter proportional to a change in the weight of a substrate by determining the difference between a first delta drive current (ΔI₁) for a substrate (seated on the indexer mechanism) prior to processing in a process module and a second delta drive current (ΔI₂) for the same substrate (reseated on the indexer mechanism 202) after processing in the process module.

In some embodiments, a process module can be configured for the deposition of a layer on a substrate by a deposition process. In such examples, the deposition process will increase the weight of the substrate. Under controlled process conditions, which eliminate process drift, the increase in substrate weight due to the deposition process and hence the difference between ΔI₁ and ΔI₂ is a precisely known parameter (the control parameter). Therefore, subsequent cycles of the same deposition process performed in the process module can be monitored for process drift since if the difference between ΔI₁ and ΔI₂ (the control parameter) deviates either from a predetermined acceptable value or a predetermined acceptable range values then a process drift is identified. In such examples, the control parameter can be communicated to an alert system (such as the controller 112, an external alert system, or a user, etc.) wherein the alert system is activated if the controller 112 determines that the control parameter is outside a predetermined value or range of values.

It should be noted that the exemplary apparatus and methods outlined above can also be employed for substrates undergoing etching processes in a process modules where the etching process will decrease the weight of the substrate.

In accordance with additional examples of the disclosure, one or more environmental sensors 230 can be disposed within the load lock body 108, as illustrated in FIG. 2. In alternative embodiments, the environmental sensors 230 can be constructed and arranged to monitor the environment within the load lock body 108 externally (e.g., via the use of viewing ports, access lines, and the like). In accordance with examples of the disclosure, the environmental sensors 230 can be employed to monitor a number of environmental factors within the load lock body 108 including, but not limited, temperature, humidity, and vacuum level (i.e., pressure). In some embodiments, the environmental sensors 230 are in communication with the controller 112 to allow for monitoring of the environment within the load lock body 108. In such examples, the controller 112 can also intervene if the monitored environment is outside of optimal or pre-determined conditions. For example, such an intervention by the controller 112 may include altering the temperature, the humidity and/or vacuum level within the load lock body 108 by communication between the controller 112 and one or more heaters, humidifies, and/or vacuum pumps (not illustrated in FIG. 2).

In accordance with examples of the disclosure, the environmental sensors 230 in conjunction with the controller 112 and means for altering the internal environment within the load lock body 108 (e.g., heaters, humidifiers, vacuum pumps, and the like) can be employed to maintain the internal environment within the load lock body 108 in a stable steady state between seating and reseating a substrate on the indexer mechanism 202. In such examples, the delta drive current (ΔI) and particular the difference between ΔI₁ and ΔI₂ used to generate the control parameter can be determined with increased accuracy when the environment with the load lock body 108 is maintained at stable steady state (i.e., whilst maintaining a substantially equal temperature, humidity, and vacuum level within the load lock body). Therefore, in such examples, the accuracy of the control parameter, which is directly proportional to either the weight or weight change of the substrate, can be maintained or even improved upon. As a non-limiting examples, the load lock arrangement 200 of the present disclosure may determine a weight change in a substrate (post deposition and/or etch) to less than 1 microgram, or less.

In accordance with further examples of the disclosure, the load lock arrangement 200 of FIG. 2 may also include a temperature control plate 222. The temperature control plate 222 can incorporate heating means and/or cooling means (e.g., via heating elements, cooling channels, and the like) in order to control the temperature of the substrate 118 within the load lock body 108. In some embodiments, the indexer mechanism 202 can be positioned proximate to the temperature control plate 222 for improved thermal communication between the substrate 118 disposed on the indexer mechanism 202 and the temperature control plate 222. In such examples, the temperature control plate 222 can be employed to maintain or alter the temperature of the substrates 118 such that the accuracy of the control parameter (e.g., determined via the difference between ΔI₁ and ΔI₂) is improved by allowing steady state evaluation of the substrate 118 (i.e., the temperature of the substrate 118 is the same during the determination of ΔI₁ and ΔI₂), for example.

It should be noted that although the load lock arrangement as illustrated in FIG. 2 is illustrated as including a single chamber, it should be appreciated that the apparatus and methods described above can be readily applied to a load lock arrangement including an upper load lock chamber and a lower load lock chamber (i.e., a dual chamber load lock arrangement). As a non-limiting example, the load lock arrangement 200 as illustrated in FIG. 2 could comprise an upper load lock chamber of a dual chamber load lock arrangement and a second indexer mechanism could be structured and arranged to operator in a lower load lock chamber with minor alterations to the position and configuration of an additional indexer mechanism.

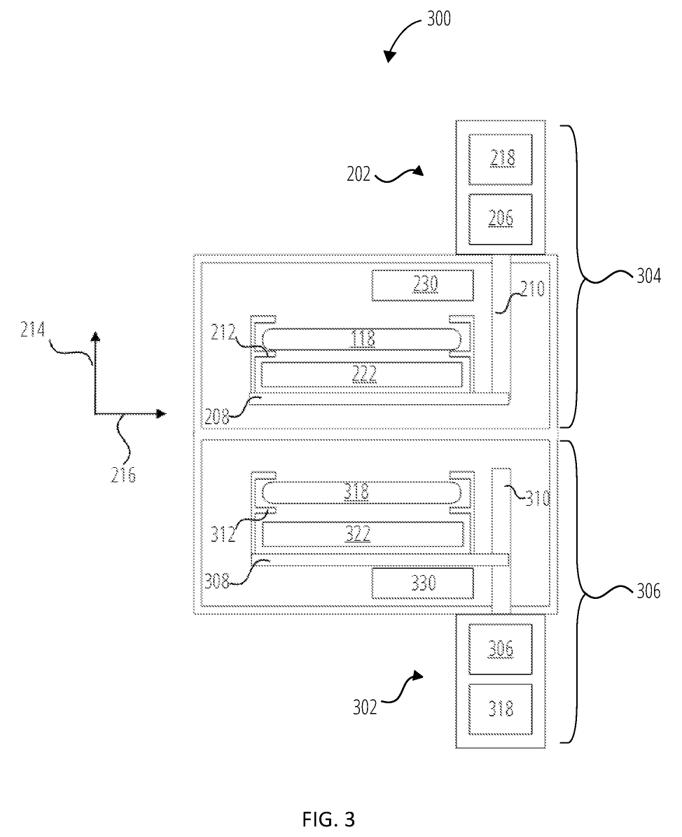

As a non-limiting example FIG. 3 illustrates an exemplary dual load lock arrangement 300 including an upper load lock chamber 304 (equivalent to the load lock arrangement 200 of FIG. 2) and a lower load lock chamber 306. The dual chamber load dual lock arrangement 300 of FIG. 3 has been simplified to better illustrate the configuration of elements within the dual load lock arrangement 300 and corresponding load lock elements from the upper load lock chamber 304 present in the lower load lock chamber 306 have been numerically labelled beginning with a “3” rather than a “2” to indicate the element is a component of the lower load lock chamber 306. As lustrated in FIG. 3, a lower indexer mechanism 302 for the lower load lock chamber 306 has been be inverted (from that illustrated in FIG. 2) to allow for operation in the lower load lock chamber 306 of the dual load lock arrangement 300, in addition to minor reconfiguration of the lower indexer mechanism 302 to better accommodate substrate 318 and the lower temperature control plate 322.

In accordance with examples of the disclosure, the load lock arrangement 200 (FIG. 2) can be utilized as part of a semiconductor processing system, such as the exemplary semiconductor processing system 100 of FIG. 1. In such examples, and with reference to FIG. 1 and FIG. 2, the semiconductor processing system 100 includes a load lock arrangement 200 including load lock body 108, an equipment front-end module (EFEM) 110 connected to a front face 140 of the load lock body 108, the equipment front-end module 110 housing a front-end substrate transfer robot 146, and a back-end transfer module (BETM) 104 connected to a rear face 138 of the load lock body 108, the back-end transfer module 104 coupling a process module 102 to the load lock body 108. In such examples, an indexer mechanism 202 is connected to the load lock body 108 and the index indexer mechanism 202 includes a drive mechanism 206 and a means for supporting a substrate (i.e., substrate handling members 212). In such examples, a position sensor 218 is configured and arranged to measure a deflection distance of the indexer mechanism 202 from a known neutral position upon seating a substrate 118 on the indexer mechanism 202 and subsequently generate a feedback signal based on the deflection distance. In such examples, a controller 112 is configured and arranged to receive the feedback signal and subsequently the controller calculates and provides a delta drive current (ΔI) to the drive mechanism 206 to reposition the indexer mechanism 202 back to the known neutral position, where the delta drive current (ΔI) is proportional to the weight of the substrate 118 when the acceleration of the drive mechanism 206 is zero and the vacuum load on the indexer mechanisms 202 is constant. Under such conditions, the controller 112 generates a control parameter proportional to a change in the weight of the substrate by determining the difference between a first delta drive current (ΔI₁) for a substrate transferred and seated on the indexer mechanism 202 from the equipment front-end module (EFEM) 110 and a second a delta drive current (ΔI₂) for the substrate transferred and reseated on the indexer mechanism 202 from the back-end transfer module (BETM) 104 after the substrate has been subjected to one or more process within the process module 102. In such examples the semiconductor processing system 100 further includes an alert system in communication with the controller 112 wherein the alert system is activated if the controller 112 determines that the control parameter is outside a predetermined acceptable value or range of values.

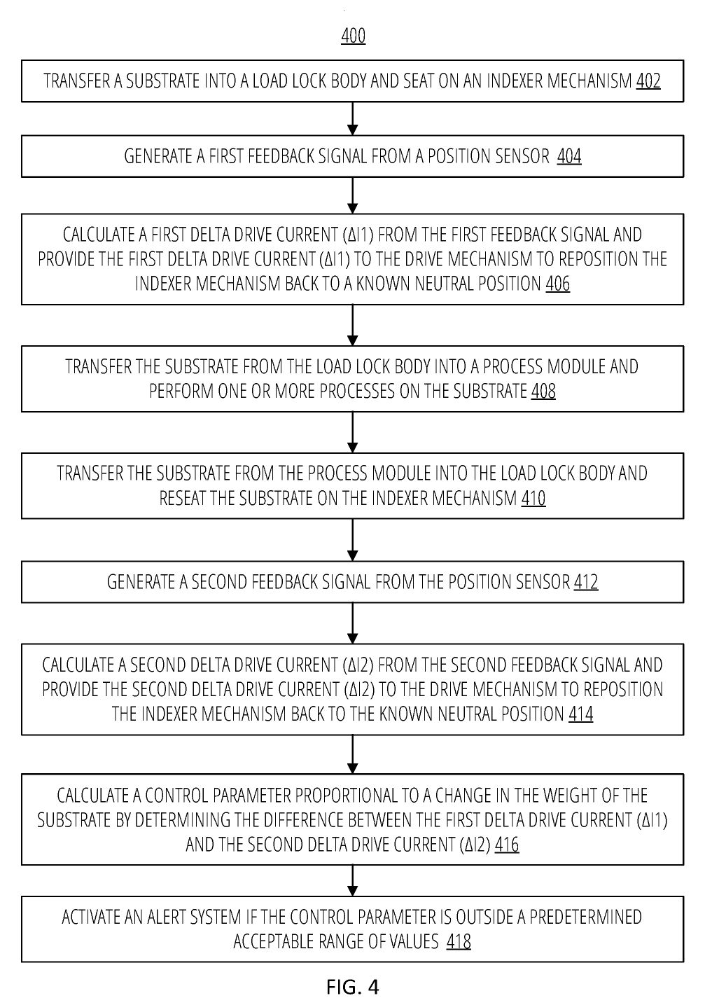

The embodiments of the present disclosure also include methods for monitoring process drift in a semiconductor processing system. In accordance with examples of the disclosure, FIG. 4 illustrates a method 400 for monitoring process drift in a semiconductor processing system. The method 400 includes providing or at an indexer mechanism connected to a load lock body, the indexer mechanism including a drive mechanism and a means for supporting a substrate.

In accordance with examples of the disclosure, the method 400 continues with step 402 which comprises, transferring a substrate into the load lock body and seating the substrate on the indexer mechanism.

In accordance with examples of the disclosure, the method 400 continues with step 404 which comprises, generating a first feedback signal from a position sensor configured and arranged to measure a first deflection distance of the indexer mechanism from a known neutral position upon seating the substrate on the indexer mechanism.

In accordance with examples of the disclosure, the method 400 continues with step 406 which comprises, calculating a first delta drive current (ΔI₁) from the first feedback signal and providing the first delta drive current (ΔI₁) to the drive mechanism to reposition the indexer mechanism to the known neutral position, where the first delta drive current (ΔI) is proportional to the first weight of the substrate when the acceleration of the drive mechanism is zero and the vacuum load on the indexer mechanism is constant.

In accordance with examples of the disclosure, the method 400 continues with step 408 which comprises, transferring the substrate from the load lock body into a process module and performing one or more processes on the substrate.

In accordance with examples of the disclosure, the method 400 can continue with step 410 which comprises, transferring the substrate from the process module into the load lock body assembly and reseating the substrate on the indexer mechanism.

In accordance with examples of the disclosure, the method 400 continues with step 412 which comprises, generating a second feedback signal from the position sensor configured and arranged to measure a second deflection distance of the indexer mechanism from the known neutral position upon reseating the substrate on the indexer mechanism.

In accordance with examples of the disclosure, the method 400 continues with step 414 which comprises, calculating a second delta drive current (ΔI₂) from the second feedback signal and providing the second delta drive current (ΔI₂) to the drive mechanism to reposition the indexer mechanism to the known neutral position, where the second delta drive current (ΔI) is proportional to the second weight of the substrate when the acceleration of the drive mechanism is zero and the vacuum load on the indexer is constant.

In accordance with examples of the disclosure, the method 400 continues with step 416 which comprises, calculating a control parameter proportional to a change in the weight of the substrate by determining the difference between the first delta drive current (ΔI₁) and the second delta drive current (ΔI₂).

In accordance with examples of the disclosure, the method 400 can continue with step 418 which comprises, activating an alert system if the control parameter is outside a predetermined acceptable range of values.

In accordance with additional examples of the disclosure, method 400 further comprises employing one or more environmental sensors in communication with a controller, the environmental sensors being configured and arranged to monitor one or more of the temperature, the humidity, and the vacuum level within the load lock body. In such examples, the environmental sensors can be employed to monitor a number of environmental factors within the load lock body including, but not limited, temperature, humidity, and vacuum level (i.e., pressure). In such examples, the environmental sensors can communicate with the controller to allow for monitoring of the environment within the load lock body. Further in such examples, the controller is configured to intervene if the monitored environment within the load lock body is outside of optimal or pre-determined conditions. For example, such an intervention by the controller can include altering the temperature, the humidity and/or vacuum level within the load lock body 108 via communication between the controller 112 and one or more heaters, humidifies, and/or vacuum pumps. Therefore, in some embodiments the method 400 further comprises maintaining an environment within the load lock body (i.e., the temperature, the humidity, the vacuum level, and the like) in a steady state condition when calculating the first delta drive current and the second delta drive current. In such examples, the calculation of the first delta drive current and the second delta drive current is performed in substantially the same environment within the load lock body.

In accordance with additional examples of the disclosure, method 400 can further comprise maintaining the temperature of the substrate in a steady state (i.e., at a constant temperature) when calculating the first delta drive current and the second delta drive current by positioning a temperature control proximate to the substrate, as described in detail previously herein.

In accordance with further examples of the disclosure, method 400 can further comprise performing one or more corrective measures to bring the control parameter within the predetermined acceptable range of values when the alert system is activated. For example, when the alert system is activated a process drift within a process module is detected. As such, the controller or user intervention can be activated to correct the process drift detected within the process module. As non-limiting examples, the corrective measures can include, but are not limited, cleaning of the process module, evaluation of the components within the process module, evaluation of the precursors and/or reactants fed to the process module, and inspection of the processed substrate for abnormalities.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. An apparatus for monitoring process drift in a semiconductor processing system, the apparatus comprising:
a load lock arrangement including a load lock body;
an indexer mechanism connected to the load lock body and including a drive mechanism and a means for supporting a substrate; and
a position sensor configured and arranged to measure a deflection distance of the indexer mechanism from a known neutral position upon seating the substrate on the indexer mechanism and subsequently the position sensor generates a feedback signal based on the deflection distance;
a controller configured and arranged to receive the feedback signal and subsequently calculate and provide a delta drive current (ΔI) to the drive mechanism to reposition the indexer mechanism back to the known neutral position, where the delta drive current (ΔI) is proportional to the weight of the substrate when the acceleration of the drive mechanism is zero and the vacuum load is constant, such that the controller is enabled to generate a control parameter proportional to either a weight of the substrate or a change in the weight of the substrate; and
an alert system in communication with the controller wherein the alert system is activated if the controller determines that the control parameter is outside a predetermined acceptable range of values.

2. The apparatus of claim 1, wherein the position sensor comprises a linear position sensor.

3. The apparatus of claim 2, wherein the linear position sensor is integrated within the indexer mechanism.

4. The apparatus of claim 2, wherein the linear position sensor is a parallel plate capacitor sensor or a laser triangulation displacement sensor.

5. The apparatus of claim 1, wherein the drive mechanism comprises a linear motor drive.

6. The apparatus of claim 1, further comprising one or more environmental sensors in communication with the controller, the environmental sensors being configured and arranged to monitor one or more of the temperature, the humidity, and the vacuum level within the load lock body.

7. The apparatus of claim 1, wherein the load lock arrangement comprises a dual load lock arrangement comprising a lower indexer mechanism.

8. The apparatus of claim 1, further comprising a temperature control plate disposed proximate to the substrate, the temperature control plate configured to control the temperature of the substrate.

9. A semiconductor processing system comprising;
a load lock arrangement including a load lock body
an equipment front-end module (EFEM) connected to a front face of the load lock body, the EFEM housing a front-end substrate transfer robot;
a back-end transfer module (BETM) connected to a rear face of the load lock body, the BETM coupling a process module to the load lock body;
an indexer mechanism connected to the load lock body and including a drive mechanism and a means for supporting a substrate;
a position sensor configured and arranged to measure a deflection distance of the indexer mechanism from a known neutral position upon seating the substrate on the indexer mechanism and subsequently the position sensor generates a feedback signal based on the deflection distance;
a controller configured and arranged to receive the feedback signal and subsequently calculate and provide a delta drive current (ΔI) to the drive mechanism to reposition the indexer mechanism back to the known neutral position, where the delta drive current (ΔI) is proportional to the weight of the substrate when the acceleration of the drive mechanism is zero and the vacuum load is constant, such that the controller is enabled to generate a control parameter proportional to a change in the weight of the substrate by determining the difference between a first delta drive current (ΔI₁) for the substrate transferred and seated on the indexer mechanism from the EFEM and a second a delta drive current (ΔI₂) for the substrate transferred and seated on the indexer mechanism from the BETM after the substrate has been subjected to one or more process within the process module; and
an alert system in communication with the controller wherein the alert system is activated if the controller determines that the control parameter is outside a predetermined acceptable range of values.

10. The semiconductor processing system of claim 9, wherein the position sensor comprises a linear position sensor.

11. The semiconductor processing system of claim 10, wherein the linear position sensor is integrated with the indexer mechanism.

12. The semiconductor processing system of claim 9, wherein the drive mechanism comprises a linear motor drive.

13. The semiconductor processing system of claim 9, further comprising one or more environmental sensors in communication with the controller, the environmental sensors being configured and arranged to monitor one or more of the temperature, the humidity, and the vacuum level within the load lock body.

14. The semiconductor processing system of claim 9, further comprising a temperature control plate disposed proximate to the substrate, the temperature control plate configured to control the temperature of the substrate.

15. The semiconductor processing system of claim 9, wherein the load lock arrangement comprises a dual load lock arrangement comprising a lower indexer mechanism.

16. A method of monitoring process drift in a semiconductor processing system, the method comprising:
at an indexer mechanism connected to a load lock body and including a drive mechanism and a means for supporting a substrate;
transferring the substrate into the load lock body and seating the substrate on the indexer mechanism;
generating a first feedback signal from a position sensor configured and arranged to measure a first deflection distance of the indexer mechanism from a known neutral position upon seating the substrate on the indexer mechanism;
calculating a first delta drive current (ΔI₁) from the first feedback signal and providing the first delta drive current (ΔI₁) to the drive mechanism to reposition the indexer mechanism back to the known neutral position, where the first delta drive current (ΔI) is proportional to a first weight of the substrate when the acceleration of the drive mechanism is zero and the vacuum load is constant;
transferring the substrate from the load lock body into a process module and performing one or more processes on the substrate;
transferring the substrate from the process module into the load lock body assembly and reseating the substrate on the indexer mechanism;
generating a second feedback signal from the position sensor configured and arranged to measure a second deflection distance of the indexer mechanism from the known neutral position upon reseating the substrate on the indexer mechanism;
calculating a second delta drive current (ΔI₂) from the second feedback signal and providing the second delta drive current (ΔI₂) to the drive mechanism to reposition the indexer mechanism back to the known neutral position, where the second delta drive current (ΔI₂) is proportional to a second weight of the substrate when the acceleration of the drive mechanism is zero and the vacuum load is constant;
calculating a control parameter proportional to a change in the weight of the substrate by determining the difference between the first delta drive current (ΔI) and the second delta drive current (ΔI); and
activating an alert system if the control parameter is outside a predetermined acceptable range of values.

17. The method of claim 16, further comprising one or more environmental sensors in communication with a controller, the environmental sensors being configured and arranged to monitor one or more of the temperature, the humidity, and the vacuum level within the load lock body.

18. The method of claim 17, further comprising maintaining an environment within the load lock body in a steady state condition when calculating the first delta drive current and the second delta drive current.

19. The method of claim 16, further comprising maintaining the temperature of the substrate in a steady state when calculating the first delta drive current and the second delta drive current by positioning a temperature control proximate to the substrate.

20. The method of claim 16, further comprising performing one or more corrective measures to bring the control parameter within the predetermined acceptable range of values when the alert system is activated.
